(19) United States
(12) Patent Application Publication
(10) Pub. No.: US 2025/0286522 A1
(43) Pub. Date: Sep. 11, 2025

(54) PAD ATTENUATOR TO IMPROVE RECEIVER LINEARITY

(71) Applicant: Silicon Laboratories Inc., Austin, TX (US)

(72) Inventors: Pavel Konecny, San Jose, CA (US); Mohamed Elkholy, Cedar Park, TX (US); Christopher Calvo, Plantation, FL (US)

(21) Appl. No.: 18/601,087

(22) Filed: Mar. 11, 2024

(51) Int. Cl. H03F 3/24

(52) U.S. Cl. CPC H03F 3/245; H03F 2200/294; H03F 2200/451

(57) ABSTRACT

In one aspect, an apparatus comprises: a low noise amplifier (LNA) to receive and amplify a receive radio frequency (RF) signal; a power amplifier (PA) to amplify a transmit RF signal and output the amplified transmit RF signal at an output node of the PA; a blocking capacitor coupled to the output node of the PA; an input/output (I/O) pad coupled to the output node, the I/O pad to interface with an antenna; and a pad attenuator coupled to the output node of the PA, the pad attenuator to attenuate the receive RF signal in a receive mode and minimize a load on the PA in a transmit mode.

### BACKGROUND

In wireless devices having receivers, an attenuator is a commonly used component to reduce the signal level of blocking signals. Typically, the attenuator is formed of dedicated circuitry and is located in close proximity to receiver circuitry such as a low noise amplifier (LNA). However conventional attenuators have a limited ceiling with respect to receive linearity, where further attenuation does not improve lineup IIP3. This is due to preceding circuitry in the lineup that limits linearity. Such non-linearity is especially prevalent where receiver and transmitter portions of a transceiver share pad circuitry, and additional circuitry is present at this pad circuitry, which can degrade the impact of this conventional attenuator circuitry.

### SUMMARY OF THE INVENTION

In one aspect, an apparatus comprises: a low noise amplifier (LNA) formed on a semiconductor die to receive and amplify a receive radio frequency (RF) signal; a power amplifier (PA) formed on the semiconductor die to amplify a transmit RF signal and output the amplified transmit RF signal at an output node of the PA; a blocking capacitor formed on the semiconductor die coupled to the output node of the PA; an input/output (I/O) pad coupled to the output node, the I/O pad to interface with an antenna coupled to the semiconductor die; and a pad attenuator formed on the semiconductor die and coupled to the output node of the PA, the pad attenuator to attenuate the receive RF signal in a receive mode and minimize a load on the PA in a transmit mode.

In an implementation, the PA and the pad attenuator are to share the blocking capacitor. The pad attenuator may be configured to: operate with a first voltage from a first regulator associated with the PA in the transmit mode; and operate with a second voltage from a second regulator associated with the LNA in the receive mode, the first voltage greater than the second voltage. The pad attenuator may include: a programmable resistor; and at least one switch coupled to the programmable resistor.

In an implementation, the apparatus further comprises a controller coupled to the at least one switch to control the at least one switch to couple a selected resistance of the programmable resistor to the output node, where the selected resistance is to couple between the output node and the blocking capacitor. The at least one switch may be implemented as a plurality of first metal oxide semiconductor field effect transistors (MOSFETs) and the programmable resistance comprises a plurality of first resistors, each of the plurality of first resistors coupled between the output node and one of the plurality of first MOSFETs. The at least one switch may further include a plurality of second MOSFETs, each of the plurality of second MOSFETs coupled to one of the plurality of first MOSFETs.

In an implementation, the pad attenuator further comprises a second programmable resistor, the second programmable resistor comprising a plurality of second resistors, each of the plurality of second resistors coupled to one of the plurality of second MOSFETs. In the transmit mode, the controller is to cause the plurality of second MOSFETs to be disabled. In the receive mode, the controller is to selectively enable at least one of the plurality of second MOSFETs to couple a selected resistance of the plurality of first resistors to the output node.

In an implementation, the apparatus further comprises an RF attenuator coupled to the LNA, where the controller, in the receive mode, is first to enable the RF attenuator and thereafter enable the pad attenuator. The apparatus may further include a harmonic filter coupled between the output node of the PA and the pad attenuator, the harmonic filter comprising an inductor coupled in series with a programmable capacitance.

In another aspect, a method includes: in a transmit mode in which a first PA of a wireless device is transmitting a first RF signal: powering a pad attenuator coupled between an output of the first PA and an I/O pad that outputs the first RF signal with a first regulated voltage, the first regulated voltage provided to the first PA; causing first switches of the pad attenuator to be disconnected; and causing second switches of the pad attenuator to be biased in a weak region to protect the pad attenuator in the transmit mode; and in a receive mode in which a LNA coupled to the I/O pad is receiving a second RF signal, attenuating the second RF signal via the pad attenuator.

In an implementation, the method further comprises in the receive mode, powering the pad attenuator with a second regulated voltage, the second regulated voltage provided to the LNA. The method may include in the receive mode, causing one or more of the first switches of the pad attenuator to be connected to provide a selected amount of attenuation of the second RF signal. The method may include providing a control code to the first switches of the pad attenuator to cause the one or more of the first switches of the pad attenuator to be connected to provide the selected amount of attenuation of the second RF signal.

In an implementation, the method further comprises in the receive mode: first attenuating the second RF signal using a RF attenuator coupled to the LNA; and further attenuating the second RF signal using the pad attenuator.

In yet another aspect, a system includes: a LNA formed on a semiconductor die to receive and amplify a receive RF signal; a first PA formed on the semiconductor die to amplify a first transmit RF signal and output the amplified first transmit RF signal at a first output node of the first PA; a second PA formed on the semiconductor die to amplify a second transmit RF signal and output the amplified second transmit RF signal at a second output node of the second PA; an output path coupled to the first output node of the first PA and the second output node of the second PA; a blocking capacitor coupled to the output path; an I/O pad coupled to the output path, the I/O pad to interface with an antenna coupled to the semiconductor die; and a pad attenuator formed on the semiconductor die and coupled to the output path, the pad attenuator to use the blocking capacitor in a receive mode and the first PA to use the blocking capacitor in a transmit mode.

In an implementation, the pad attenuator comprises: a plurality of first linearization resistors, each of the plurality of first linearization resistors coupled to a gate terminal of a corresponding first MOSFET; and a plurality of second linearization resistors, each of the plurality of second linearization resistors coupled between an output terminal of a corresponding second MOSFET and the output path.

In an implementation, the system further comprises a harmonic filter coupled to the output path, the harmonic filter comprising an inductor coupled in series with a programmable capacitance.

### BRIEF DESCRIPTION OF THE DRAWINGS

FIG. 1 is a schematic diagram of a portion of a wireless device in accordance with an embodiment.

FIG. 2 is a schematic diagram of details of a pad attenuator in accordance with an embodiment.

FIG. 3 is a flow diagram of a method in accordance with an embodiment.

FIG. 4 is a block diagram of a representative integrated circuit that incorporates an embodiment.

FIG. 5 is a high level diagram of a network in accordance with an embodiment.

### DETAILED DESCRIPTION

In various embodiments, attenuator circuitry for attenuating undesired incoming RF signals (such as blocker signals) and/or attenuating very strong desired incoming RF signals is physically located at a transceiver input pad to enable greater receiver linearity. This attenuator circuitry located directly at this pad can minimize a received voltage signal at the pad, and thus improve receiver linearity. At the same time, this attenuator circuitry is leveraged to share at least some circuitry of a transmitter, reducing chip real estate.

At a high level this attenuation circuitry, referred to herein as a pad attenuator, is used to improve RF front end receiver linearity in the presence of a large blocker signal. For example, the blocker may be a transmitted Wi-Fi signal output from a Wi-Fi transmitter, which may be present within the same wireless device as the receiver (e.g., implemented on the same circuit board as the receiver circuitry).

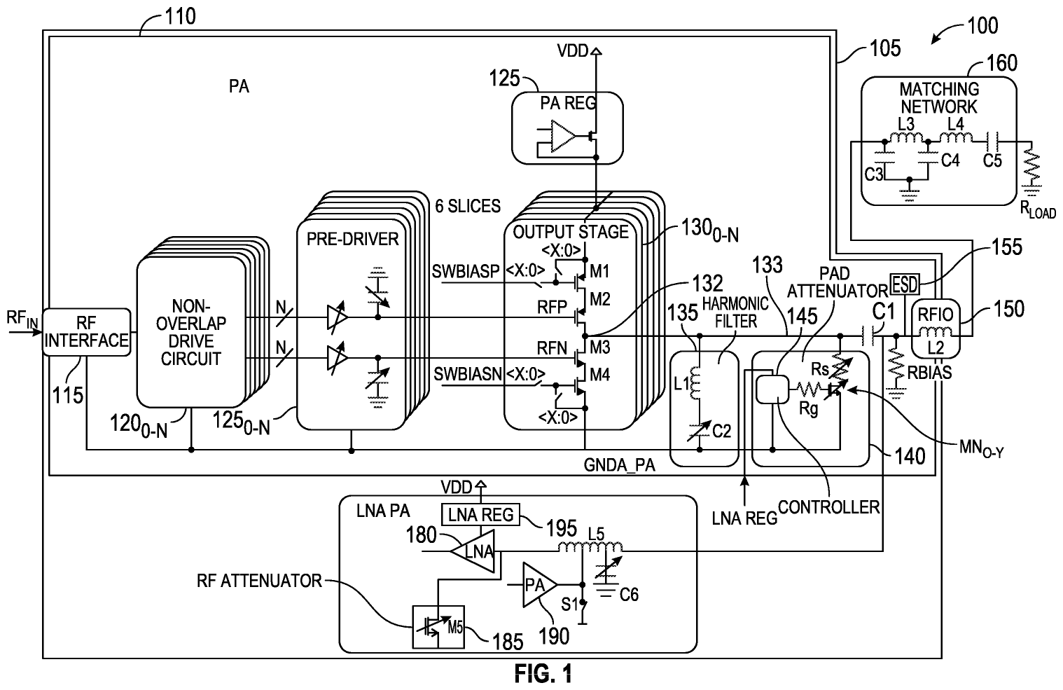

Referring now to FIG. 1, shown is a schematic diagram of a portion of a wireless device in accordance with an embodiment. As shown in FIG. 1, wireless device 100 may be any type of wireless device, ranging from small Internet of Things (IoT) devices to larger devices such as smartphones, tablet computers, laptop computers, to even larger systems, such as client computer systems, wireless TVs and so forth. In the high level shown in FIG. 1, a transceiver circuit 105 is adapted on a semiconductor die. Although the embodiment of FIG. 1 shows transceiver circuit 105 implemented on a single semiconductor die, embodiments are not limited in this regard.

As shown, transceiver circuit 105 includes a first power amplifier (PA) 110 and a second PA 190. In an embodiment, PAs 110, 190 may be implemented as Bluetooth low energy (BLE) PAs, with first PA 110 implemented as a 10 decibel-milliwatt (dBm) PA, and second PA 190 implemented as a 0 dBm PA. Of course other implementations may have PAs of different power levels and/or wireless protocols.

As further shown, a low noise amplifier (LNA) 180 also is present. In the embodiment shown, LNA 180 is preceded by an RF attenuator 185 that is meant to protect LNA 180 from blockers. However the preceding blocks in the lineup which include PA 190, PA 110, and electrostatic discharge (ESD) circuitry 155 all see the blocker signal at the maximum level no matter the attenuation level of RF attenuator 185, which limits receiver linearity. Thus with embodiments herein, pad attenuator 140 is co-located with PA 110 in order to provide protection for all blocks in the lineup including those preceding LNA 180, improving linearity of the receiver as a whole.

Still with reference to FIG. 1, RF signals to be transmitted are received in an RF interface 115 of PA 110 and are provided to a non-overlap drive circuit 120, which may be used to transform the RF signal into a differential RF signal and provide drive control. Although embodiments are not limited in this regard, non-overlap drive circuit 120 may be implemented with a plurality of units or slices. In a particular implementation there may be six slices present.

The resulting differential RF signal is provided to a pre-driver circuit 125_{0-N}, which also may be implemented with a plurality of slices. In an embodiment, there may be six slices of pre-driver circuit 125. In embodiments, pre-driver circuit 125 may further provide edge control, e.g., via included programmable capacitors coupled to the output of pre-drivers present within each of the slices. The resulting differential RF signals are provided to a corresponding plurality of output stages 130_{0-N}. In the implementation of FIG. 1, there are six output stage slices.

As shown, each output stage 130 includes a series stack of metal oxide semiconductor field effect transistors (MOSFETs), namely, plural N-channel MOSFETs (NMOS) and P-channel MOSFETs (PMOS). More specifically as shown, a first PMOS M1 may be switchably controlled by an incoming bias signal (SWBIASP<X:0>) to couple between a supply voltage node and a pass device M2 (implemented as another PMOS device), which couples between PMOS M1 and an output node 132. Similarly, a first NMOS M4 may be switchably controlled by an incoming bias signal (SWBIASN<X:0>) to couple between a reference voltage node and another NMOS device M3, which couples between NMOS M4 and output node 132. In a particular implementation, each slice may include a plurality of units, e.g., sixteen units, such that there may be sixteen sets of the transistor stack shown in FIG. 1 in each slice (where each set can be individually controlled).

Via output stage 130, an amplified RF signal is output via output node 132. As shown, the amplified RF signal passes along an output path 133 through a DC block capacitor C1, and is output from transceiver circuit 105 via an RF input/output (RFIO) pad 150 including a parasitic inductance associated with package bond-wire (represented as an inductor L2).

Still referring to FIG. 1, a transmit harmonic filter 135 is adapted along output path 133. As shown, harmonic filter 135 couples between output path 133 and a reference voltage node, which in an embodiment is a PA ground node. In the high level view shown in FIG. 1, harmonic filter 135 is implemented with a series-coupled inductor L1 and a programmable capacitance C2.

In an implementation, PA 110 has a class-D PA architecture that provides efficiency and overall simplicity for fixed envelope modulations, such as BLE Gaussian frequency shift keying (GFSK). However, meeting out-of-band emissions, like FCC restricted band etc., can be difficult due to the hard-switching nature of a class-D PA. With embodiments, harmonic filter 135 operates as a series LC circuit shunting the PA output, to provide improvement for odd harmonics by diverting the H3 current to this on-chip loop inductor that radiates more effectively than an external loop. In embodiments, harmonic filter 135 may be implemented with a large tuning range (via the tunable capacitor C2) to cover both H3 and H5.

Also coupled to output path 133 is a pad attenuator 140. Essentially, pad attenuator 140 is implemented as a programmable resistor designed for RF frequencies (e.g., 2.4-2.48 GHz BLE band in this case) that attenuates a RF blocker signal received via an antenna (such as represented by the load impedance R_{LOAD}). Attenuation capability of pad attenuator 140 may be based at least in part on the level of resistance; in a particular implementation, pad attenuator 140 is configured to attenuate up to 11 dBm blocker power levels.

In the high level view shown in FIG. 1, pad attenuator 140 includes a controller 145 that is configured to control a programmable amount of attenuation via a programmable resistor Rs that in turn couples to a programmable switch, e.g., implemented as a plurality of NMOS devices Mn_{0-Y}. Understand that FIG. 1 is at a high level of generality and embodiments may include additional switches as part of pad attenuator 140. Note that control signals provided to gate terminals of NMOS devices Mn may couple through a protection resistor Rg. As shown in the embodiment of FIG. 1, pad attenuator 140, which provides receiver attenuation for LNA 180, couples between output path 133 and the PA reference node. In the high level shown, pad attenuator 140 is located within PA 110, although it provides attenuation for LNA 180. More generally, pad attenuator 140 may be more closely physically located to PA 110 than LNA 180.

Thus as shown in FIG. 1, pad attenuator 140 is illustrated as being embedded in PA 110, and is directly connected to its output, and by proxy RFIO pad 150. With this positioning in a receiver lineup, blockers are attenuated directly at RFIO pad 150. In contrast, without an embodiment, blocking signals first hit ESD circuitry 155 or the output of PA 110, causing non-linearities to develop and thus limiting receive performance. Stated another way, pad attenuator 140 can greatly improve linearity in backoff by reducing the signal level before subsequent circuits that share RFIO pad 150 (ESD circuitry 155 and PA 110) can contribute significant non-linearities.

In addition, the location of pad attenuator 140 behind blocking capacitor C1 enables reuse, as this PA DC blocking capacitor and a receiver attenuator AC coupling capacitor are merged into a single capacitor. In addition, this positioning of pad attenuator 140 does not negatively impact PA loading impedance, and thus there is very little degradation of PA efficiency.

Still referring to FIG. 1, transceiver circuit 105 couples to a matching network 160. In embodiments, matching network 160 may be implemented as an off-chip matching network, e.g., implemented on a circuit board on which transceiver circuit 105 is adapted. In the high level shown in FIG. 1, matching network 160 is implemented with series-coupled inductors L3, L4 and capacitor C5 and parallel capacitors C3 and C4. In turn, matching network 160 couples to a load, e.g., a given antenna, represented in FIG. 1 as a load resistance R_{load}.

Still referring to FIG. 1, LNA 180 couples to pad 150 through an inductor L5. With embodiments, LNA 180 may be provided with attenuation via both pad attenuator 140 and an RF attenuator 185. In embodiments, RF attenuator 185 may be implemented as a passive network attenuator, e.g., implemented with a programmable resistance controlled by NMOS device(s) M5, and coupled between the LNA input and ground (which may be a different ground than the PA ground).

As further shown, for transmit operations via second PA 190, an incoming RF signal is amplified and output through inductor L5 to output pad 150. A switch S1 couples to PA 190 and acts as a transmit/receive switch to protect the LNA input in a transmit mode from voltage overstress generated by PA 110. A capacitor C6 is coupled in parallel to inductor L5.

A LNA regulator 195 provides a regulated voltage for LNA 180 and PA 110. Note that this regulated voltage may be at a lower level than the regulated voltage of PA 110 provided by PA REG 125. In a particular embodiment, PA regulator 125 provides a 1.45 volt (v) regulated voltage, while LNA regulator 195 provides a 0.9 v regulated voltage. As will be described herein, pad attenuator 140 may operate using either voltage. Although shown at this high level in the embodiment of FIG. 1, understand that many variations and alternatives are possible.

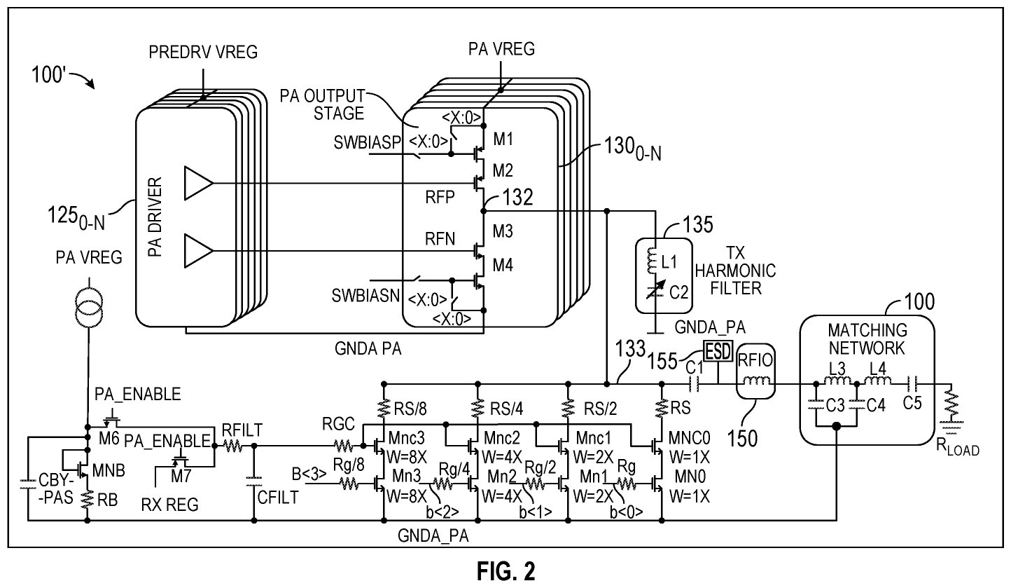

Referring now to FIG. 2, shown is a schematic diagram that illustrates further details of a pad attenuator in accordance with an embodiment. As illustrated in FIG. 2, wireless device 100′ may be implemented the same as in FIG. 1, and thus, various components are shown with the same enumeration and are not further discussed.

Note that in FIG. 2, further details of pad attenuator 140 are illustrated. Specifically, pad attenuator 140 includes a plurality of programmable resistors RS-RS/8 that couple between output path 133 and the PA reference node. More specifically, each of these programmable resistors may be implemented as a binary weighted resistor that is controlled to be selectively enabled or disabled via a pair of series-coupled MOSFETs, namely corresponding ones of so-called protection NMOS devices Mn_{C0}-Mn_{C3} and switch NMOS devices Mn₀-Mn₃.

As shown, each switch NMOS device Mn is controlled by a corresponding bit of a control word b[3:0]. In embodiments, this control word may be received from controller 145 of pad attenuator 140. When enabled, the corresponding switch NMOS Mn is closed, thus coupling the corresponding resistance Rs.

In turn, NMOS devices Mn_{C} act as protection devices when operation is in a transmit mode. In this transmit mode, switch NMOS devices Mn are disabled. And protection devices Mnc are weakly on, providing protection to the switch devices, which are formed of thin film devices. In the transmit mode, the DC bias at the gate terminals of protection devices Mnc is approximately 0.45V. The AC RF voltage at these gate terminals is weakly following the RF voltage at the output of PA 110 (which is the same as the voltage at the drain terminals of protection devices Mnc), limiting voltage stress between Vgate-drain.

In an embodiment, MOSFETs Mn and Mnc may be implemented as thin oxide devices (e.g., having a length of approximately 30 nm). As a result, there can be silicon area savings and lower parasitic capacitance, so as to not impact PA loading impedance and having negligible impact on a LNA noise figure. The various resistors Rg and Rs can be implemented with linearization resistors to significantly improve attenuator linearity. In addition, gate resistors Rg also improve ESD performance, essentially enabling MOSFETs Mnc to be self-protecting in the presence of fast transients.

Pad attenuator 140 is powered by one of multiple voltages. More specifically, pad attenuator 140 receives a first regulated voltage from a first voltage regulator (PA regulator 125) associated with PA 110 when in a transmit mode, and instead receives a second regulated voltage from a second voltage regulator (LNA regulator 195) associated with LNA 180 when in a receive mode. As shown, each of these regulated voltages are provided through a corresponding MOSFET M6, M7, which are controlled by an enable signal. When PA 110 is active, pad attenuator 140 receives a first regulated voltage from first voltage regulator 125. Instead, when LNA 180 is active, pad attenuator 140 receives a second regulated voltage from second voltage regulator 195. Although shown at this high level in the embodiment of FIG. 2, many variations and alternatives are possible. For example, while FIG. 2 shows a four-bit implementation, embodiments are not limited in this regard and a pad attenuator may include more or fewer programmable resistors and associated switches.

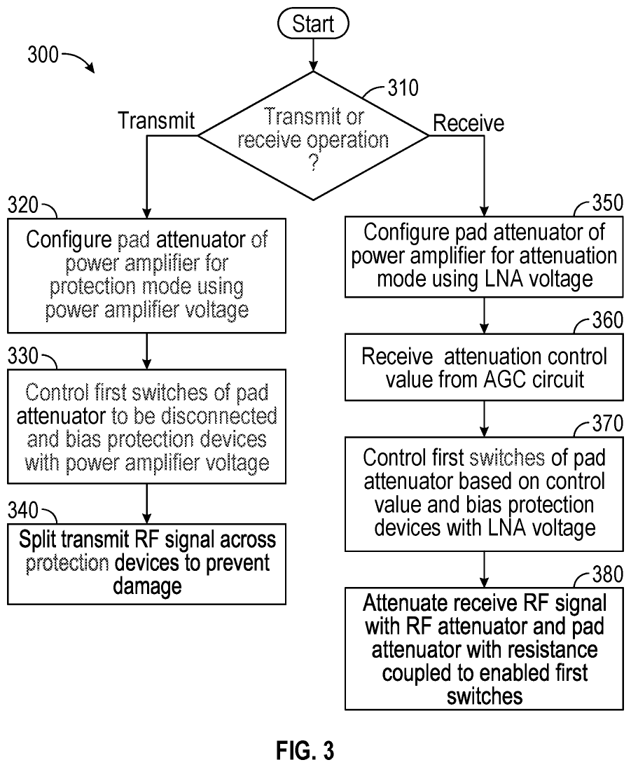

Referring now to FIG. 3, shown is a flow diagram of a method in accordance with an embodiment. As shown in FIG. 3, method 300 is a method for controlling a pad attenuator. As such, method 300 may be performed by a controller such as a controller included in or coupled to the pad attenuator. Such controller may perform method 300 alone and/or in combination with instructions of firmware and/or software. Such instructions may be stored in a non-transitory storage medium.

Method 300 begins by determining whether operation is in a transmit or receive mode (diamond 310). When it is determined that the transmit mode is active, control passes to block 320 where the pad attenuator of the PA can be configured for a protection mode. In this protection mode, the pad attenuator is powered using a PA regulated voltage. In this mode, the switch devices of the pad attenuator may be disabled, e.g., by providing a control word having all zero values to gate terminals of the switch devices. Thus at block 330, first switches of the pad attenuator are controlled to be disconnected. At the same time, protection devices of the pad attenuator may be biased using the PA regulated voltage to be weakly on to provide protection to the switching transistors. In this transmit mode, the transmit RF signal may be split across the protection devices, protecting the various MOSFETs (block 340). Stated another way, the RF signal at an output path is divided down, so that voltages seen by MOSFETs of the pad attenuator are smaller than this full swing signal. Associated power losses are small, and thus that this protection circuitry has only a small effect on PA efficiency.

Still referring to FIG. 3, in a receive mode, control passes to block 350 where the pad attenuator of the PA can be configured for an attenuation mode. In this attenuation mode, the pad attenuator is powered using a LNA regulated voltage. Next at block 360, an attenuation control value is received. In an embodiment, this attenuation control value, which is a control code that is provided to the gate terminals of switching devices, may be received from an automatic gain control (AGC) circuit that controls a desired level of attenuation based at least in part on the signal level of a blocker and/or receive RF signal. Note that in the receive mode, the pad attenuator may as a secondary function protect the LNA.

Control next passes to block 370, where one or more selected switch devices of the pad attenuator are enabled by providing a control value having at least some logic high values to gate terminals of the switch devices. At the same time, protection devices of the pad attenuator are biased using the LNA regulated voltage. Finally, at block 380, the receive RF signal may be attenuated with one or more of an RF attenuator and the pad attenuator. In one implementation, attenuation control may be performed by first enabling and increasing an attenuation level of the RF attenuator, e.g., until it reaches a given level (which may be its maximum level or some threshold level). Thereafter, based on the attenuation control value, the pad attenuator is enabled with a selected amount of resistance coupled via the enabled switch devices. Although shown at this high level in the embodiment of FIG. 3, many variations and alternatives are possible.

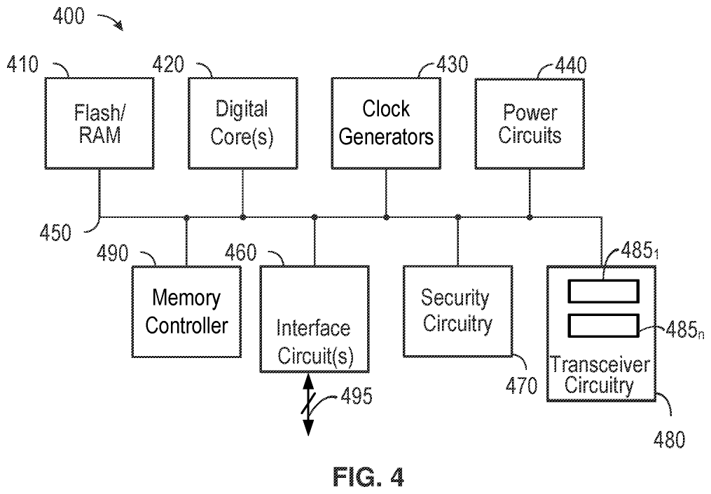

Referring now to FIG. 4, shown is a block diagram of a representative integrated circuit 400 that includes a pad attenuator included in PA circuitry to provide attenuation for incoming RF signals, while enabling circuit reuse and improving receiver linearity, as described herein. In the embodiment shown in FIG. 4, integrated circuit 400 may be, e.g., a dual mode wireless transceiver that may operate according to one or more wireless protocols (e.g., WLAN and Bluetooth, among others) or other device that can be used in a variety of use cases. In one or more embodiments, the circuitry of integrated circuit 400 shown in FIG. 4 may be implemented on a single semiconductor die.

Integrated circuit 400 may be included in a range of devices including a variety of stations, including smartphones, wearables, smart home devices, IoT devices, other consumer devices, or industrial, scientific, and medical (ISM) devices, among others.

In the embodiment shown, integrated circuit 400 includes a memory system 410 which in an embodiment may include volatile storage, such as RAM and non-volatile memory as a flash memory. The flash memory is a non-transitory storage medium that can store instructions and data. Such non-volatile memory may store instructions, including instructions for determining an appropriate configuration of a pad attenuator (and/or an RF attenuator) based at least in part on a level of an incoming RF signal, as well as differently controlling the pad attenuator in a transmit mode, as described herein. As further shown integrated circuit 400 also may include a memory controller 490.

Memory system 410 couples via a bus 450 to one or more digital cores 420, which may include one or more cores and/or microcontrollers that act as processing units of the integrated circuit. In turn, digital cores 420 may couple to clock generators 430 which may provide one or more phase locked loops or other clock generator circuitry to generate various clocks for use by circuitry of the IC.

As further illustrated, IC 400 further includes power circuitry 440, which may include one or more voltage regulators, including such voltage regulators for PAs and LNAs as described herein. Additional circuitry may be present depending on particular implementation to provide various functionality and interaction with external devices. Such circuitry may include interface circuitry 460 which provides a digital communication interface with additional circuitry (such as a memory, to couple to IC 400 via a link 495. IC 400 also may include security circuitry 470 to perform wireless security techniques.

In addition, as shown in FIG. 4, transceiver circuitry 480 may be provided to enable transmission and receipt of wireless signals, e.g., according to one or more of a local area or wide area wireless communication scheme, such as Zigbee, Bluetooth, IEEE 802.11, IEEE 802.15.4, cellular communication or so forth. As shown, transceiver circuitry 480 includes multiple PAs 4851-n, at least one of which may include pad circuitry as described herein. Understand while shown with this high level view, many variations and alternatives are possible.

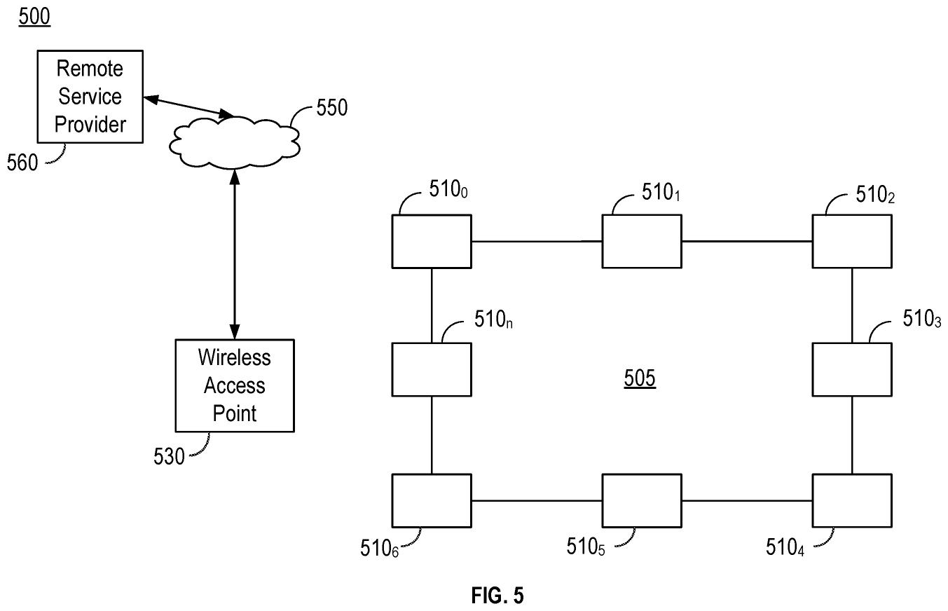

ICs such as described herein may be implemented in a variety of different devices such as wireless stations, IoT devices or so forth. Referring now to FIG. 5, shown is a high level diagram of a network in accordance with an embodiment. As shown in FIG. 5, a network 500 includes a variety of devices, including wireless stations including smart devices such as IoT devices, access points and remote service providers, which may leverage embodiments for providing pad attenuator circuitry as described herein.

In the embodiment of FIG. 5, a wireless network 505 is present, e.g., in a building having multiple wireless devices 5100-n. As shown, wireless devices 510 couple to an access point 530 that in turn communicates with a remote service provider 560 via a wide area network 550, e.g., the internet. Understand while shown at this high level in the embodiment of FIG. 5, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a low noise amplifier (LNA) formed on a semiconductor die to receive and amplify a receive radio frequency (RF) signal;
a power amplifier (PA) formed on the semiconductor die to amplify a transmit RF signal and output the amplified transmit RF signal at an output node of the PA;
a blocking capacitor formed on the semiconductor die coupled to the output node of the PA;
an input/output (I/O) pad coupled to the output node, the I/O pad to interface with an antenna coupled to the semiconductor die; and
a pad attenuator formed on the semiconductor die and coupled to the output node of the PA, the pad attenuator to attenuate the receive RF signal in a receive mode and minimize a load on the PA in a transmit mode.

2. The apparatus of claim 1, wherein the PA and the pad attenuator are to share the blocking capacitor.

3. The apparatus of claim 1, wherein the pad attenuator is to:
operate with a first voltage from a first regulator associated with the PA in the transmit mode; and
operate with a second voltage from a second regulator associated with the LNA in the receive mode, the first voltage greater than the second voltage.

4. The apparatus of claim 1, wherein the pad attenuator comprises:
a programmable resistor; and
at least one switch coupled to the programmable resistor.

5. The apparatus of claim 4, further comprising a controller coupled to the at least one switch to control the at least one switch to couple a selected resistance of the programmable resistor to the output node, wherein the selected resistance is to couple between the output node and the blocking capacitor.

6. The apparatus of claim 5, wherein the at least one switch comprises a plurality of first metal oxide semiconductor field effect transistors (MOSFETs) and the programmable resistance comprises a plurality of first resistors, each of the plurality of first resistors coupled between the output node and one of the plurality of first MOSFETS.

7. The apparatus of claim 6, wherein the at least one switch further comprises a plurality of second MOSFETs, each of the plurality of second MOSFETs coupled to one of the plurality of first MOSFETs.

8. The apparatus of claim 7, wherein the pad attenuator further comprises a second programmable resistor, the second programmable resistor comprising a plurality of second resistors, each of the plurality of second resistors coupled to one of the plurality of second MOSFETs.

9. The apparatus of claim 8, wherein in the transmit mode, the controller is to cause the plurality of second MOSFETs to be disabled.

10. The apparatus of claim 9, wherein in the receive mode, the controller is to selectively enable at least one of the plurality of second MOSFETs to couple a selected resistance of the plurality of first resistors to the output node.

11. The apparatus of claim 5, further comprising an RF attenuator coupled to the LNA, wherein the controller, in the receive mode, is first to enable the RF attenuator and thereafter enable the pad attenuator.

12. The apparatus of claim 1, further comprising a harmonic filter coupled between the output node of the PA and the pad attenuator, the harmonic filter comprising an inductor coupled in series with a programmable capacitance.

13. A method comprising:
in a transmit mode in which a first power amplifier (PA) of a wireless device is transmitting a first radio frequency (RF) signal:
powering a pad attenuator coupled between an output of the first PA and an input/output (I/O) pad that outputs the first RF signal with a first regulated voltage, the first regulated voltage provided to the first PA;
causing first switches of the pad attenuator to be disconnected; and
causing second switches of the pad attenuator to be biased in a weak region to protect the pad attenuator in the transmit mode; and
in a receive mode in which a low noise amplifier (LNA) coupled to the I/O pad is receiving a second RF signal, attenuating the second RF signal via the pad attenuator.

14. The method of claim 13, further comprising in the receive mode, powering the pad attenuator with a second regulated voltage, the second regulated voltage provided to the LNA.

15. The method of claim 13, further comprising in the receive mode, causing one or more of the first switches of the pad attenuator to be connected to provide a selected amount of attenuation of the second RF signal.

16. The method of claim 15, further comprising providing a control code to the first switches of the pad attenuator to cause the one or more of the first switches of the pad attenuator to be connected to provide the selected amount of attenuation of the second RF signal.

17. The method of claim 15, further comprising in the receive mode:
first attenuating the second RF signal using a RF attenuator coupled to the LNA; and
further attenuating the second RF signal using the pad attenuator.

18. A system comprising:
a low noise amplifier (LNA) formed on a semiconductor die to receive and amplify a receive radio frequency (RF) signal;
a first power amplifier (PA) formed on the semiconductor die to amplify a first transmit RF signal and output the amplified first transmit RF signal at a first output node of the first PA;
a second PA formed on the semiconductor die to amplify a second transmit RF signal and output the amplified second transmit RF signal at a second output node of the second PA;
an output path coupled to the first output node of the first PA and the second output node of the second PA;
a blocking capacitor coupled to the output path;
an input/output (I/O) pad coupled to the output path, the I/O pad to interface with an antenna coupled to the semiconductor die; and
a pad attenuator formed on the semiconductor die and coupled to the output path, the pad attenuator to use the blocking capacitor in a receive mode and the first PA to use the blocking capacitor in a transmit mode.

19. The system of claim 18, wherein the pad attenuator comprises:
a plurality of first linearization resistors, each of the plurality of first linearization resistors coupled to a gate terminal of a corresponding first metal oxide semiconductor field effect transistor (MOSFET); and
a plurality of second linearization resistors, each of the plurality of second linearization resistors coupled between an output terminal of a corresponding second MOSFET and the output path.

20. The system of claim 18, further comprising a harmonic filter coupled to the output path, the harmonic filter comprising an inductor coupled in series with a programmable capacitance.
